(19) United States
(12) Patent Application Publication
(10) Pub. No.: US 2002/0061665 A1
(43) Pub. Date: May 23, 2002

(54) Method and apparatus for vertically stacking and interconnecting ball grid array (BGA) electronic circuit devices

(76) Inventor: Victor Batinovich, San Martin, CA (US)

Correspondence Address: CENTRAL COAST PATENT AGENCY, PO BOX 187, AROMAS, CA, 95004, US

(21) Appl. No.: 10/047,858

(22) Filed: Jan. 14, 2002

Related U.S. Application Data
(63) Continuation-in-part of application No. 09/915,708, filed on Jul. 25, 2001.
Application No. 09/915,708 is a continuation-in-part of application No. 09/609,626, filed on Jul. 3, 2000.

(51) Int. Cl. H05K 1/00; H01R 12/00

(52) U.S. Cl. 439/71

(57) ABSTRACT

A method for forming an extended solder column on a contact pad of an electronic device comprises steps of (a) applying a solder seed to the contact pad; (b) contacting the seed with a surface substantially parallel to and opposite the contact pad, with the seed between the surface and the pad; (c) melting the seed to wet the contact pad and the surface; (d) extending the relative separation of the surface and the contact pad, drawing the molten seed into a column; and (e) solidifying the resultant column. Further in the invention an integrated circuit (IC) assembly for mounting to a surface of a device board comprises a plurality of planar ICs interspersed with individual interposers or a or continuous interposer and conductive bars for constraining the stack and providing conductive paths to the device board.

### CROSS-REFERENCE TO RELATED DOCUMENTS

The present application is a continuation-in-part (CIP) of a pending patent application bearing the Ser. No. 09/915,708 entitled “Method and Apparatus for Increasing Density of a Memory Module Without Increasing Size” which is itself a CIP of a co-pending application bearing the Ser. No. 09/609,626, entitled “Method and Apparatus for Applying a Protective Over-Coating to a Ball Grid Array (BGA) structure” , both of which are incorporated herein in their entirety by reference.

### FIELD OF THE INVENTION

The present invention is in the field of low-profile electronic circuit devices and pertains in particular to methods and apparatus for electronic circuit interconnection and vertical stacking of chip-scale ball grid array (BGA) circuit devices in a high-density memory module.

### BACKGROUND OF THE INVENTION

The field of integrated circuit interconnection and packaging is a rapidly evolving technology associated with semiconductor manufacturing, and due to the currently relentless miniaturization trend in portable products that utilize integrated circuit devices, much work in the field is focused on reducing the package size of an integrated device while increasing performance and functionality of the device. While there are natural limits on the minimum useful size of hand-operated electronic devices that utilize keypads and displays, such as wireless communication or personal digital assistant (PDA) devices, for example, the drive to reduce the size and mass of the printed circuit assembly continues.

Several well-established miniaturization solutions have been developed to reduce the size and number of components in an electronic integrated device, and to increase the assembly density of the device itself. Silicon integration utilizing advanced photolithography techniques, for example, continues to provide opportunities to place more functionality on a single chip or multiple pieces of silicon, whichever delivers the optimal combination of price and performance. Ball grid array (BGA), chip-scale package (CSP), and solder-bumped flip-chip technologies are at the forefront in this advanced manufacturing process, allowing manufacturers an immediate gain in space savings with minimal investment when used with recent silicon designs or current surface mount technology (SMT) assembly processes. For these technologies, solder is typically the electrical and mechanical connection medium, and solder joint performance and reliability is one of the most critical issues in the development of these technologies.

Integrated circuit packaging techniques using ball grid array (BGA) contacts have provided opportunity for dramatic reductions in overall component area as well as a much broader latitude in I/O. BGA packaging is seen by many as a viable answer to the space restrictions typical of newer generations of electronic products, with continuing emphasis on improved functionality and higher performance. Chip-stacking, where two chips are stacked inside a thin small outline package (TSOP), a method well-known in the art, has one chip face-up in the package and the other face-down, both chips being wire bonded to the leadframe on each side. A significant limitation exists, however, utilizing the described technique in that it is only practically applied using the same memory chips, (DRAMs for example), with one chip processed as a mirror-image of the other, in order to simplify wire bonding.

Multi-level electronics assembly utilizing some form of chip stacking has become well known in the industry, but its use in mainstream electronics manufacturing has, so far, been somewhat limited. The complexity of stacking chips, packages or modules has limited chip-stack packaging techniques to low-volume specialized applications such as military electronics, high-speed computers and implantable medical devices, for example. Currently, the largest trend in chip-stacking technology known to the inventor is a simple approach with only two chips in one package. The simple stacking technique provides a package that is smaller than a traditional two-dimensional printed circuit board assembly, but not as complex as a three-dimensional assembly, for example, which employs vertical electrical circuit buses, as is known in current art.

Several types of well-known stacked chip packages exist for use with different types of chip devices such as DRAMs and flash memory, for example, and are increasingly employed in electronic products such as hand-held computers or cellular telephones, and elsewhere where density and low profile is of importance. A chip scale package (CSP), when assembled using current ball grid array (BGA) manufacturing techniques, is a package commonly used in such applications, allowing for a much finer solder bump pitch and greatly increased number of I/O connections.

Recent solutions utilizing CSP devices incorporating area-array solder bump technology such as BGA, and other wafer-level packaging schemes known to the inventor, utilize solder ball interconnection methods that provide a certain level of strength and protection to the much smaller connection leads from damage, while eliminating the need for outer-edge pad arrangements such as used for conventional TSOP memory chips, for example. Prior-art methods providing additional protection from damage to the wafer or substrate are also commonly employed in the industry, whereby a protective coating of non-conductive material such as a polyamide layer, for example, is applied to the wafer or substrate. The dielectric protective layer is intended to protect circuits from contaminants and damage, and through chemical etching or other known method, the connection pads of the die are subsequently exposed. A typical prior-art protective layer such as described above, however, provides little mechanical protection to the die pads themselves, nor to the connection points between solder balls and the die pads. Although in many cases the use of the dielectric coating improves the results obtained in the bumping and assembly process of the wafer, it is not a requirement for effective formation of the conductive bumps on the flip chip, and in some applications, such as when photoemmiter or photodetector devices are being packaged, the dielectric coating step is eliminated entirely.

Although flip-chip technology provides definite advantages over traditional Surface Mount Technology (SMT) packages, as solder ball pitches become tighter and solder connections become smaller, reliability of the solder interconnections is becoming an increasing area of concern in the application. The solder interconnections utilized in CSP and BGA technologies are much smaller than those of traditional Surface Mount Technology (SMT) interconnections, for example, and, as is known in the art, a higher coefficient of thermal expansion (CTE) mismatch typically exists between the silicon die and the organic substrates commonly used in such applications, due to the nature of the differing materials used. To address this problem manufacturers have incorporated, in addition to other protective steps described above, a wafer contact protection and strengthening process, whereby, once the wafer has been bumped and the solder bumps have been cured, an epoxy underfill is flowed between the connection side of the flip chip and the substrate, or intermediate printed circuit board, that is used for mounting the flip chip. The cured underfill, in many cases, enhances the strength of the flip chip assembly and provides environmental protection to eliminate corrosion or electrical migration that might result in electrical failures. The low coefficient of thermal expansion of the underfill also provides dimensional stability to resist thermal shock in the operating environment.

Several enhancements to protection processes such as those described above are known to the inventor for techniques utilized in wafer-level packaging for CSP devices of BGA technology. One such enhanced BGA method known to the inventor, and the subject of a separate patent application referenced above, which is not prior art, involves application of a protective polymer coating that is applied to the silicon wafer substrate using, for example, a spin-application technique, prior to the step of separation of the devices from the wafer. During application the protective polymer coating flows over existing conductive pads to which the conductive leads of the device, in this case solder balls, have been metallurgically attached, completely covering the solder balls and conductive pads. Once cured, the polymer coating material is evenly removed from the surface of the substrate by etching or by mechanical process, until upper portions of the covered solder balls become exposed. The described process is taught in the patent application Ser. No. 09/609,626, which is referenced above as a priority document.

The achievement of rapid advances in integration density and performance of large-scale integration (LS I) devices is predicated on increasing the total number of I/O and power/ground terminals, which, in turn, leads to shrinking design rule of wiring and solder bump pitch on the organic substrate of a flip-chip package. However, decreasing the bump pitch and wiring rule raises the process cost of fabricating the organic substrate. Moreover, it is difficult to obtain highly reliable connections between chip and organic substrate with smaller solder bumps due to the mismatching of the coefficient of the thermal expansion (CTE). To overcome these problems, direct chip attachment architectures have been developed, such as flip chip on board (FCOB) providing a vital step towards miniaturization. In such architecture an adapter-like device is used to allow a connector of one size and style to connect to a mating connector of a different type and style. The adapting device, or interposer as it is termed in the industry, is manufactured of a low-cost substrate material such as FR-4, or may be manufactured of other organic or inorganic materials. The recent use of interposers using a silicon substrate with through-connections has partially addressed the thermal expansion mismatch between conventional silicon dies and organic substrates, and has allowed manufacturers to obtain connections between chip and substrate that are more reliable with minimal propagation delay.

Utilizing chip stacking techniques coupled with assembling CSP devices using BGA technology substantially increases price-performance, capacity and reliability. The contributions described above with respect to mentioned processes known to the inventor provide considerable strengthening and improved signal propagation than do known prior-art methods. An enhanced method and apparatus for a chip integration technique is known to the inventor, and is taught in the patent application Ser. No. 09/915,708 entitled “Method and Apparatus for Increasing Density of a Memory Module Without Increasing Size ” , which is referenced above as a priority document. The method and apparatus enables a chip integration technique to be applied to device boards wherein memory, and in some cases other functional ICs, may be integrated and added to a device board without requiring dimension increases in existing form-factors. The technique involves a flexible interposer trace board having a substrate manufactured of non-conductive sheet material, with conducting metal traces and contact pads which may be provided by a metallic foil applied to non-conductive sheet by an adhesive, or the traces and pads may be formed in a metallic film layer deposited on the interfacing material using a metal deposition technique such as sputtering technology, for example. Conductive traces and pads on the sheet material may, in some cases, be accessible from both sides of the interposer, being exposed at selected regions throughout the non-conductive sheet. The flexible interposer is positioned between the conductive surfaces of a first and second IC, the conductive surfaces of the first and second IC facing each other. The conductive traces on the non-conductive sheet material contact individual ones of the first and second pluralities of the conductive leads of the two ICs, providing conductive signal paths from the first and second ICs between the ICs, leading to edges of the IC package, and a bus bar facility positioned along at least one edge of the IC module. The bus bar facility provides conductive paths from the traces of the interposer board to selected regions of the host printed circuit module board.

In a wafer-level packaging scheme in prior art, as described above, a limitation exists in the number of I/O connections that may be used. For example, by nature of its design, a wafer-level device must be of a physical size large enough to facilitate a maximum allowable number of solder bumps and connections which, in this packaging scheme, can only be reduced in size to a certain extent in order to ensure optimal signal propagation and connection reliability. Therefore, the maximum allowable number of I/O connections in such a package is limited relative to the surface area the device itself.

The efficient redistribution of signals from peripheral contact pads of an IC device to those of an area-array configuration such as used in BGA technology, has been an area of great attention in the development of the technology, largely due to its direct impact upon the relationship between the size of the area on the chip available for connections and the number of I/O connections and circuits that are used in the interconnection process. Current manufacturing trends have resulted in contacts and connections that have been miniaturized to a point where any further miniaturization is not practical due to a resulting unstable and unreliable connection. For example, a wafer-level packaging scheme such as described above, utilizing solder column and bumping and wire-bond assembly techniques presents a limitation to the number of I/O connections possible on the chip due to the complexity of the design and the number of interconnections, power planes, and circuits necessary, and because they cannot overlap and thereby require a large surface area of the chip.

For high-density applications utilizing flip chip assembly technology it is known that many aspects of the BGA and other technologies pertaining to manufacturing and assembly that are used for wafer-level packaging schemes overlap with those used for flip chip technology. However, an advantage of the flip-chip configuration is that, since the connections can be positioned directly above circuitry and connection points of a substrate, for instance, a fewer number of solder bumps and connections of larger size can be used for the module PCB connection side to achieve a more efficient and economical redistribution of signal paths. Also the entire perimeter of the surface area of the flip-chip is made available allowing a much greater number of I/O connections. An inherent problem exists in the configuration, however, in that the solder bumps and connections between the flip chip and the substrate PCB are substantially smaller than those used for wafer-level packaging schemes, for example, thereby increasing the possibility of fatigue or failure of the connection due to lateral or vertical movement and shock, or varying thermal expansion of the organic substrate and silicon chip material.

In the manufacturing, assembly and redistribution technologies of current art described above for memory devices or other varieties of IC devices, it is desirable to have a design that utilizes as much of the surface of the silicon device as possible for I/O capacity, while at the same time minimizing the footprint of the device itself to the greatest possible extent without compromising the speed, efficiency and reliability of chip-to-chip or chip-to-board signal redistribution. In order to maximize I/O capacity of a single device while satisfying the miniaturization trends of the industry, emphasis must be placed on methods of reducing the size of I/O solder bumps and connections, for example, in such a way that connection strength, reliability and resistance to thermal expansion mismatch is maintained at the highest practical level. It has occurred to the inventors that it is desirable to have a redistribution packaging scheme for a flip-chip utilizing an area-array solder bump configuration having a pitch much finer than that which is practical for prior or current art methods as previously described, and has much smaller solder bump connections maintaining a higher level of connectivity as well as strength and flexibility in proportion to the size of the connection. It is to this goal that the method and apparatus of the present invention most particularly pertains.

What is clearly needed is a new method and apparatus for redistribution and interconnection that has connections with a high level of resilience between the connection side of a silicon chip and that of an intermediate PCB substrate material, and is also compatible with interconnection, underfill and protective coating processes known in prior and current art, and as described in various new enhancements known to the inventor and presented by patent applications identified above as priority documents. Such an enhanced packaging and interconnection scheme can be adapted to be compatible with a variety of types of IC devices including, but not limited to DRAM or other types of memory, and is of a design that is compatible with a variety of BGA manufacturing and stacked multi-level chip scale packages (CSP) therefore enabling wide acceptance and use in the industry. By utilizing such methods manufacturers may achieve instant gains in the memory capacity of a single multi-layer stacked device, for example, that are both cost-effective and readily expandable without unduly increasing the dimensions and footprint of the devices and its host module.

### SUMMARY OF THE INVENTION

In a preferred embodiment of the invention a method for forming an extended solder column on a contact pad of an electronic device is provided, comprising steps of (a) applying a solder seed to the contact pad; (b) contacting the seed with a surface substantially parallel to and opposite the contact pad, with the seed between the surface and the pad; (c) melting the seed to wet the contact pad and the surface; (d) extending the relative separation of the surface and the contact pad, drawing the molten seed into a column; and (e) solidifying the resultant column.

In a preferred embodiment there multiple contact pads on the electronic device and multiple surfaces, one for each contact pad. In some cases the surface is a second contact pad of a second electronic device, such that, after step (e) the column forms an electrical contact path between the two contact pads. Further, in some cases the surfaces are second contact pads of a second electronic device, such that, after step (e), the columns form electronic contact paths between the associated contact pads.

In some embodiments there is a further step (f) for breaking the bond at the surface to leave extended solder columns metallurgically bonded to the contact pads, and the bonds may be broken by heating the surface.

In another aspect of the invention an integrated circuit (IC) assembly for mounting to a surface of a device board comprising a plurality of planar ICs each having first contact pads on one surface, which connect to electronic devices in the IC, and conductive columns metallurgically bonded to and extending from individual ones of the contact pads, a plurality of planar interposers parallel to and interspersed with the plurality of planar ICs, each interposer having second contact pads on at least one surface connected to the conductive columns, and traces on at least one surface connected to the second contact pads, individual ones of the traces leading to electrical contact regions on an edge at a periphery of the individual interposer, the contact regions facing away from the interposer in a direction parallel with the one surface, and a plurality of conductive bars extending in a direction orthogonal to the planar ICs and interposers, the conductive bars metallurgically bonded to individual ones of the outward-facing peripheral contact regions, the bars constraining the interspersed interposers and ICs into a closely-spaced stack and providing common signal paths from the stacked ICs.

In some embodiments the conductive bars end on one side at a plane away from one end of the stacked ICs, and are connected to an intermediary board having traces and third contact pads for connecting the IC stack to a printed circuit board (PCB). Also, in some cases, the ICs are memory chips and the PCB is a memory board. In some embodiments there is a polymer material imposed between interspersed interposers and planar ICs, the polymer layer providing additional support for the stack and the conductive columns.

In still another aspect of the invention a memory module for providing memory resources to a computerized appliance is provided, comprising a printed circuit board (PCB) having at least one location for mounting an IC assembly, and an integrated circuit (IC) assembly mounted to the PCB, the assembly comprising a plurality of planar ICs each having first contact pads on one surface, which connect to electronic devices in the IC, and conductive columns metallurgically bonded to and extending from individual ones of the contact pads, a plurality of planar interposers parallel to and interspersed with the plurality of planar ICs, each interposer having second contact pads on at least one surface connected to the conductive columns, and traces on at least one surface connected to the second contact pads, individual ones of the traces leading to electrical contact regions on an edge at a periphery of the individual interposer, the contact regions facing away from the interposer in a direction parallel with the one surface, and a plurality of conductive bars extending in a direction orthogonal to the planar ICs and interposers, the conductive bars metallurgically bonded to individual ones of the outward-facing peripheral contact regions, the bars constraining the interspersed interposers and ICs into a closely-spaced stack and providing common signal paths from the stacked ICs. In a preferred embodiment there is a plurality of IC packages mounted to both sides of the circuit board of the module.

In yet another aspect an interposer for providing conductive and nonconductive interface between opposing leads of ICs stacked in a packaged IC assembly is provided, comprising a non-conductive sheet, metal contact pads and traces formed on the non-conductive sheet, including openings through the non-conductive sheet to expose regions of conductive contact pads or traces, and contact regions implemented at a periphery of the non-conductive sheet, connected to traces on the sheet, and facing outward in a direction parallel with the sheet.

In some embodiments the conductive traces and contact pads are formed from a copper foil applied to the non-conductive sheet by an adhesive, while in others the metal contact pads and traces are formed in a metallic film layer deposited on the interfacing material using one of a deposition, spin-on, or sputtering technology. The non-conductive sheet may be formed from a BT resin. In some cases the contact regions are formed by filling holes along a periphery of the non-conductive sheet with solder, then trimming the sheet through the solder-filled holes.

In still another embodiment an integrated circuit (IC) assembly for mounting to a surface of a device board is provided comprising a plurality of planar ICs each having first contact pads on one surface, which connect to electronic devices in the IC, and conductive columns metallurgically bonded to and extending from individual ones of the contact pads, an interposer formed of a length of foldable non-conductive material, folded to progressively space apart adjacent ones of the planar ICs in order, the folded interposer having second contact pads on at least one surface connected to the conductive columns of the plurality of ICs, and traces on at least one surface connected to the second contact pads, individual ones of the traces leading to electrical contact regions on the foldable interposer such that the contact regions face away from the assembly in a direction parallel with the plane of the ICs, and a plurality of conductive bars extending in a direction orthogonal to the planar ICs, the conductive bars metallurgically bonded to individual ones of the outward-facing peripheral contact regions, the bars constraining the interposer and adjacent ICs into a closely-spaced stack and providing common signal paths from the stacked ICs.

In some preferred embodiments the conductive bars end on one side at a plane away from one end of the stacked ICs, and are connected to an intermediary board having traces and third contact pads for connecting the IC stack to a printed circuit board (PCB). Also in some preferred embodiments the ICs are memory chips and the PCB is a memory board.

The IC package may further comprise a polymer material imposed between consecutive ICs and the interposer, the polymer material providing additional support for the stack and the conductive columns.

In embodiments of the invention described in enabling detail below, for the first time a method and apparatus is provided for stacking ICs in a very dense array to minimize space needed for ICs in electronic organization.

### BRIEF DESCRIPTIONS OF THE DRAWING FIGS.

FIG. 1 is a broken, cross-section view of a conventional wafer-level ball grid array (BGA) package assembled according to current ball/column lead technology.

FIG. 2 is a cross-section view of a conventional fine-pitch chip scale package (CSP) assembled according to current flip-chip technology.

FIG. 3 is an enlarged broken view of a portion of a fine-pitch chip scale package (CSP) die with an extended solder column according to an embodiment of the present invention.

FIG. 4 is an enlarged broken view of a portion of a fine-pitch chip scale package (CSP) substrate with extended solder columns according to an embodiment of present invention.

FIG. 5a is a broken plan view of an interconnection interposer according to an embodiment of the present invention.

FIG. 5b is an enlarged broken cross-section view of a portion of the interconnection interposer of FIG. 5a.

FIG. 6 is a perspective view of a vertically stacked flip-chip package assembled and interconnected according to an embodiment of the present invention.

FIG. 7 is a broken cross-section view of a portion of the stacked flip-chip package of FIG. 6, enlarged to show greater detail.

FIG. 8 is an enlarged broken cross-section view of a vertically stacked flip-chip package and interposer assembled and interconnected according to an alternative embodiment of the present invention.

### DESCRIPTION OF THE PREFERRED EMBODIMENTS

It is generally known in the various assembly, packaging and interconnection technologies used in general manufacturing of high-density ICs, such as DRAM memory devices, for example, the use of current BGA solder ball manufacturing and CSP assembly technologies allows for a much smaller form factor for IC devices than is available in prior-art methods such as single or stacked wire-bond surface mount technology (SMT), for example. Wafer-level packaging schemes, having many distinct advantages over prior methods, are becoming widely accepted in the industry, largely based on thin-film bumping and redistribution technologies. Since processing is done at wafer-level such packaging schemes allow cost savings in burn-in and testing as well as materials consumption in manufacturing,

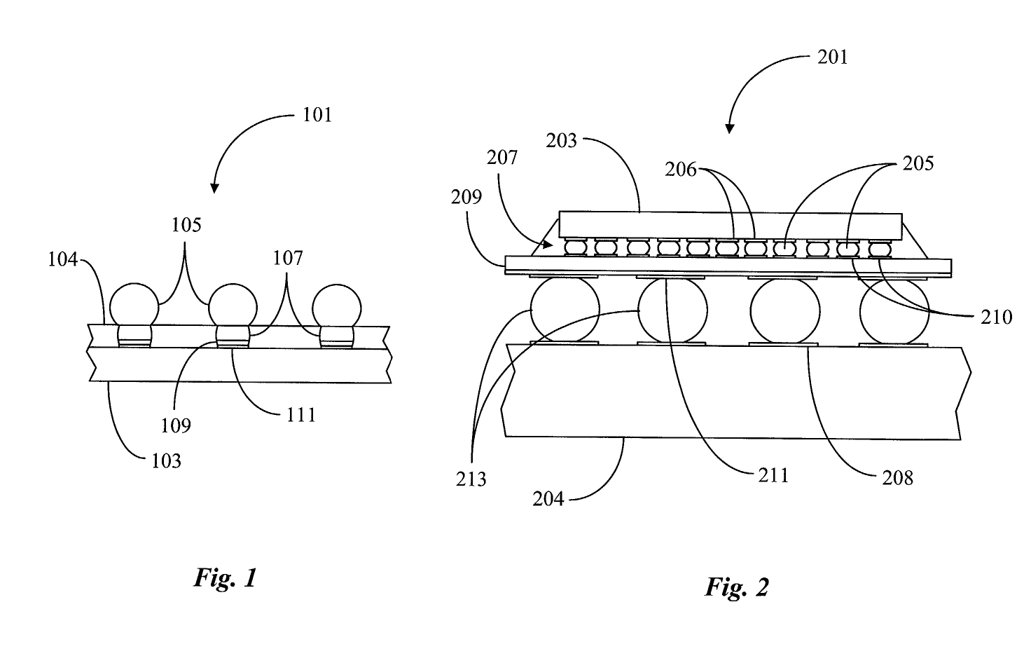

FIG. 1 is a broken cross-section view of a wafer-level ball grid array (BGA) package assembled according to a system known to the inventor using ball/column lead technology. Wafer-level package 101 has a silicon die 103 representing a conventionally known DRAM memory chip which has contact pads 111 for the purpose of electrically connecting circuitry within die 103 to circuitry outside of package 101. Pads 111 are the connection points to which wire bonding is performed after die 103 is separated from the wafer in conventional wire bonding methods. A layer of under-bump metal 109, located directly above and metallurgically attached to pads 111, improves conductivity between pads 111 and solder connection points.

In the example shown for FIG. 1 an enhanced BGA wafer-level polymer coating method, known to the inventor and described in the cross-referenced application Ser. No. 09/609,626, is used for protecting circuitry and contact points of die 103, as well as for forming a surrounding support for strengthening and protecting the solder connections. In the unique process of the cross-referenced patent application, as described earlier in the background section, solder columns 107 are formed from solder balls that have been previously metallurgically attached to the contact points of die 103, prior to wafer separation. A polymer coating 104 is then flowed over the un-separated die 103, using a spin-on method, or some other method, until the contact points, circuitry and previously attached solder balls are completely covered by the coating material. After curing, a portion of the polymer coating is removed until the upper portions of the previously attached solder balls are exposed, thereby creating a solder column 107 metallurgically attached to the contact points of die 103, supported and strengthened by the surrounding cured polymer coating, and exposed at the upper surface. Solder balls 105 are then attached to solder columns 107 of die 103 at wafer level or possibly after separation of the die from the wafer, to form the final connection points for connecting circuitry of die 103 to circuitry outside of package 101, such as that of a host PCB to which package 101 will eventually be mounted.

Solder columns 107 in this example, surrounded by the cured polymer coating 104 and exposed at the upper portion, form highly-conductive contact points that are significantly strengthened, especially laterally, by polymer coating 104, resulting in an enhanced IC device, still in wafer form, that is substantially more durable when compared to devices manufactured utilizing prior art methods that do not utilize such a solder column and polymer coating process. Extensive wafer-level testing and burn-in is now possible and practical with IC devices at wafer level utilizing the described enhanced process because pads 111 of die 103 are now protected from damage caused by probing and current flow during testing. The contact points formed by solder columns 107 are much more tolerant to probing or inadvertent damage that may be caused during testing and burn-in than are the original contact pads, and are easily repairable if such damage occurs by using solder reflow techniques, for example, or some other known method.

In this example solder columns 107, with under bump metal 109, are shown extending from pads 111 completely through polymer coating 104. However, as FIG. 1 is greatly simplified to show only an exemplary representation of a wafer-level IC package of current art, pads 111 may not necessarily be located on die 103 at locations typical of such a device, and it may be assumed that redistribution from pads 111 may be done providing conductive traces and new, additional pads of various sizes and locations on die 103.

Another clear advantage of a wafer-level package such as package 101 of FIG. 1 over previous wire-bonding SMT methods, is that, since the entire silicon surface may be utilized for solder contact placement, the I/O capacity of package 101 is greatly increased and the X and Y dimensions, or footprint, of the package is that of a single IC device itself. Another clear advantage is that IC devices manufactured with such enhancements as described for package 101 are far less susceptible to low yield and damage during manufacture, handling and assembly, and during burn-in and testing procedures.

As described in the background section there are, however, some key disadvantages with wafer-level packaging schemes. Since the interconnects, or contact pads, are located under the die in a typical configuration, achieving a very high I/O capacity die would require solder ball connections of a very small size and tight pitch. Although it is not impossible to manufacture solder balls of such size and arranged in such a tight pitch utilizing current technology, it is not practical or economical in many ways. For example, the complexity and density of circuits and connections required of the host printed wiring board (PWB) for mounting a device with such a high I/O count and tight pitch would require an expensive high-density PWB for interconnecting the I/O. It is also known in the art that in such wafer-level packaging schemes, quality differences may exist in the various areas of the silicon die in the wafer, but are nevertheless all are eventually packaged, regardless of quality. If, in the wafer-level testing and burn-in process, manufacturing yields are low, a significant penalty is exacted for packaging all of the chips on the wafer.

In the development of packaging schemes for electronics such as have been described the aim is to lower cost, increase the density of the package, and improve the performance of the device while still maintaining or even improving the reliability of the circuits and connections. The concept of the flip-chip assembly process, for example, were the semiconductor chip is assembled face-down onto a circuit board, is ideal for size considerations, because there is no extra surface area needed for contacting on the sides of the component. Increased functionality is achieved using flip-chip assembly processes because a greatly increased number of I/O's is allowed, a number not limited to the perimeter of the chip, as in wire bonding, for example. An area-array pad layout enables more signal, power and ground connections requiring less surface area. The performance in such high-frequency applications is superior to other interconnection methods, because the length of the connection path is greatly minimized. Also reliability is better than with encapsulated components due to the decreased number of connections. In flip-chip joining there is only one level of connections between the chip and the circuit board or substrate to which is mounted.

Potentially, flip-chip technology is more economical than previous methods such as wire bonding because bonding of all connections takes place simultaneously, whereas, with wire bonding, one bond is made at a time. In practice however, cost benefit is not always achieved because many of the processes involved are still, today, somewhat immature, and the cost of solder bumping a die using current processes can be significant, particularly when manufacturing volumes are low.

FIG. 2 is a cross-section view of a conventional fine-pitch chip scale package (CSP) assembled according to flip-chip technology. Flip-chip package 201 comprises a die assembly 203, with the connection side lying face down to an intermediate substrate 209. Substrate 209 in this example is an organic substrate, but in other examples may be manufactured of ceramic material, for example. Substrate 209 is an intermediate circuit board to which die 203 is interconnected and attached, having the purpose of redistributing signals from connections on the die to a printed circuit board 204 to which package 201 is mounted and interconnected. Electrical connections between die 203 and substrate 209 are made using solder balls 205 that have been previously metallurgically attached to pads 206 that are connected to the circuitry of die 203. Solder balls 205 are significantly smaller in size than those of wafer-level package 101 of FIG. 1, and in current applications may be 90 microns or less in nominal diameter. Due to the smaller size of solder balls 205 a much finer pitch, and therefore I/O capacity, is achievable using this configuration when compared to wafer-level packaging methods such as described for FIG. 1. Current flip-chip packages allow a much higher I/O count, between 500 and 3000 I/O connections for example, whereas in current wafer-level packages a maximum of only 300 I/O connections, or fewer, is possible due to the limited extent to which the solder ball connections may be practically miniaturized.

Substrate 209 has pads 210 on the upper surface to which solder balls 205 are attached, and pads 211 on the lower surface to which solder balls 213 are metallurgically attached. Solder balls 213 have the purpose of interconnecting substrate 209 to the host PCB 204, and are significantly larger in size, and fewer in number, than solder balls 205, allowing for more reliable connections between substrate 209 and host PCB 204. For fine-pitch applications the soldering process used for interconnecting the solder bumped die 203 and substrate 209, includes depositing solder onto the substrate pads 210 utilizing known methods such as a electroplating or solid solder deposition, and for courser-pitch applications solder paste is deposited on the substrate and the solder balls of the chips are placed into the solder paste and then reflowed in an oven. After the reflow process a protective epoxy underfill material, represented in this example by underfill 207, is applied by dispensing along one or two sides of the chip, from where the low viscosity epoxy is drawn by capillary forces into the space between die 203 and substrate 209, completely surrounding and encapsulated all solder connections formed by solder balls 205. Underfill 207 is then cured by heat, thereby forming environmental and mechanical protection to solder balls 205 and their connections to die 203 and substrate 209.

In flip-chip technology underfill may or may not be used, depending on the size of the die or the application in which the technology is used. Solder joint reliability for flip-chip packages is based on several factors including, but not limited to, the alloy type of the solder bump, the solder joint height, or standoff, and the distance to neutral point (DNP) which is the measurement of the center of mass of the die to the farthest solder bump on the die, typically a corner solder bump. For small die applications, where DNP is less than approximately 2 mm, package reliability is usually acceptable without the use of an epoxy underfill. In larger die packages, where DNP is between 5 and 10 mm, for example, solder joint reliability without the use of underfill depends upon the application requirements.

Although it is generally accepted that the underfill shares and reduces the solder strain level of unencapsulated solder bumps, many assemblers of chip scale package (CSP) devices prefer not to use underfill because the process of application and curing of the underfill involves excessive time and expense, thereby reducing throughput and cost-effectiveness of the manufacturing and assembly process. Since manual twisting of a printed wiring board (PWB), upon which underfilled chip packages are solder-ball-mounted, generally produces solder joint damage and failure, underfill is often used only as an extra precaution, even when accelerated lifetime studies indicate there should be no problem. Therefore, even though it may not always be necessary, underfilled chip packages are currently used in the manufacture of many small hand-held electronic devices. Although advancements in the development of improved underfill materials, as well as full wafer transfer molding technology, for example, may make the underfill option more attractive to many assemblers. However, the use of underfill materials remains largely a precautionary measure for many applications.

Underfill has been widely used in direct attachment of flip-chip-on-board (FCOB) packages, or when package leads are not robust. Various other less-conventional approaches have been used that are aimed at absorbing the CTE mismatch between the silicon die and PCB to which it is mounted within the package, or externally through various strain-absorbing mechanisms, which reduce stress on the solder interconnects. Such approaches to the CTE mismatch problem, can, however, introduce their own unique damage since the weakest link will be transferred from solder to other areas of the attachment system.

Several disadvantages exist with conventional underfilled flip-chip packaging schemes that are manufactured and assembled using such as are used in the example presented in FIG. 2. One key disadvantage is that, with present-day underfill materials, the process of applying and curing the underfill constitutes a significant step in the manufacturing process and requires considerable curing time, resulting in significantly decreased throughput and added expense. Also, repairing of the flip-chip solder joint, should damage occur, is usually very difficult or impossible after the underfill process. Therefore, testing can only be performed after the steps of die and substrate preparation, and picking, alignment and placement of the solder connections, and the reflow soldering step, but before the application and curing of the underfill material.

Another key disadvantage that exists with conventional flip-chip packaging schemes is that, in such technology, as the solder bump pitches become tighter, and the number of solder bumps used in the package becomes very high, a significant challenge is presented for the PCB or PWB industry due to the added expense and complexity of the board to which the flip-chip package is to be mounted. The separate cost factors of solder-bumping the die and of the various assembly and underfill processes for most common flip-chip technologies also have separate impacts on the final cost-effectiveness of the entire manufacturing and assembly process. The die bumping costs are dependent on wafer size, number of dies per wafer, and wafer yield and volume, and the many steps involved in assembly and the underfill process, as well as the cost of the necessary equipment and floor space, the capacity of the equipment and its compatibility with other manufacturing processes are also very important factors having influence on the economy of the technology for a particular product. It is therefore desirable to have a flip-chip package that has a strong process compatibility with current surface mount technology (SMT), having robust and reliable connections to the PCB or PWB, without requiring the use of underfill material, while simultaneously enabling a greatly increased number of I/O connections in the package.

As previously described, although it is generally accepted that the use of underfill material between the connection side of a solder bumped die and the mating surface of a substrate or PCB to which it is mounted reduces the solder strain level of unencapsulated solder bumps, many manufacturers or assemblers in the fine-pitch chip scale package (CSP) industry prefer not to use underfill due to the additional time and expense involved in the application and curing processes, particularly when accelerated lifetime studies indicate there should be no problem. Since solder joint reliability for flip-chip packages is based on many factors including, for example, the alloy type of the solder bumps, the solder joint height, and the distance to neutral point (DNP) of the pitch of the solder bumps in the chip package, the use of underfill may not be necessary in many cases. In the absence of the use of underfill in the manufacturing and assembly of such high-density devices, a flexible and robust solder connection is necessary between the die and substrate of the flip-chip package to ensure reliability and performance of the interconnection, and to reduce the overall time and expense involved in the manufacturing and assembly processes. Due to the extremely small size of the solder bumps and tight pitch of the area array in such a package, an alternative approach to solder bumping the die or substrate in such a package is needed in order to ensure connection reliability and robustness in lieu of using the underfill process. It is the goal of the inventor to provide such an alternative solder bumping approach that provides such attributes.

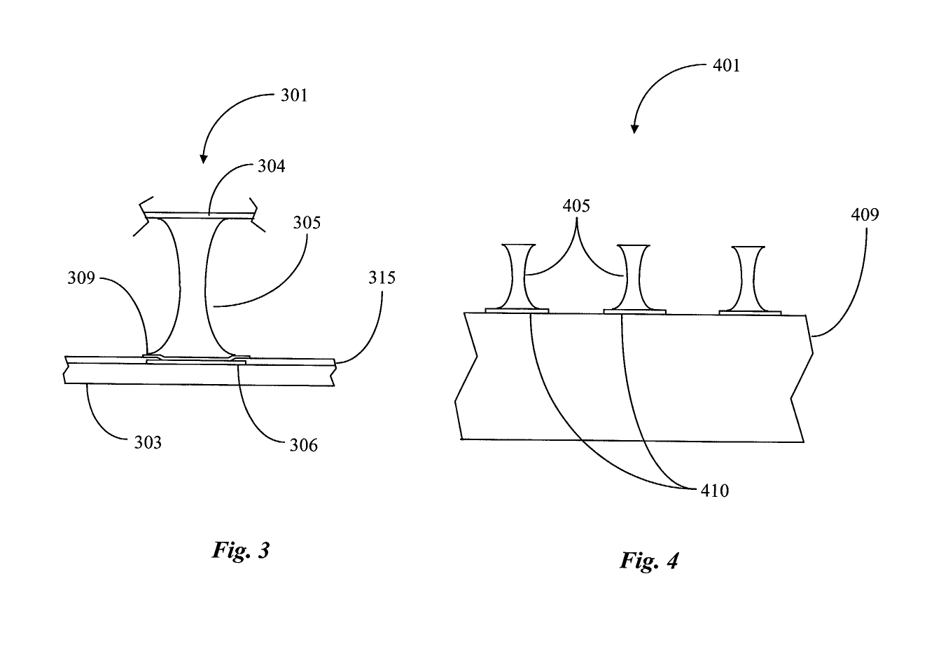

FIG. 3 is an enlarged broken view of a portion of a fine-pitch chip scale package (CSP) die with an extended solder column according to an embodiment of the present invention. An exemplary representation is provided in this view of an alternative solder bumping approach that provides a flexible and robust solder interconnection eliminating the need for using underfill material for strengthening the interconnection between the die and substrate or PCB in a fine-pitch CSP application. Silicon die 301 in this example represents a portion of a DRAM memory chip, but in other examples utilizing the enhanced solder-bumping process taught herein, die 301 may be one of a variety of types of integrated circuits.

Die 301 has a contact pad 306 for the purpose of electrically connecting circuitry within die 301 to circuitry outside of the device. A passivation layer 315, commonly used in such an application, is an applied layer typically comprising glass and/or silicon nitride, that forms an insulating layer protecting circuits and connection points of die 301 during and after assembly of the package. A final mask and passivation etch removes the passivation material from the contact terminal, represented in this example by pad 306. Under bump metal (UBM) 309, also typically used in such an application, improves electrical connectivity between pad 306 and circuits outside of die 301.

In a typical application according to flip-chip processes of conventional art, a very small solder bump, which may be as small as 90 microns in diameter, or even less, forms the solder connection between the die and the substrate or PCB to which it is mounted. In such a conventional application, due to the small size of the solder bump and its lack of robustness, an underfill material is typically used to surround and support the small solder bumps, even if accelerated lifetime studies indicate that the underfill process may not be necessary.

In this example however, the inventor provides a solder interconnection that is substantially more flexible and less prone to damage caused by shock, lateral movement between the die and substrate or PCB, or coefficient thermal expansion (CTE) mismatch between the materials of the die and substrate or PCB. Element 305 in a preferred embodiment is provided as an extended solder column having a diameter considerably less than that of solder bumps used in conventional flip-chip applications, as have been previously described. Element 304 in this example represents that surface in any application to which the solder connection provided by element 305 connects. This will typically be a pad for the purpose on another device or board.

A unique difference between columns 305 and conventional fine-pitch solder bumps is that element 305 has a substantially greater vertical height, or standoff, then that of conventional flip-chip solder bumps. The longer and thinner solder column provided by element 305 significantly increases the flexibility of the solder connection, greatly reducing the possibility of damage to the solder joint due to lateral movement or CTE mismatch.

One method by which the extended solder columns may be formed in a preferred embodiment of the invention is by a manipulation technique. In typical processes, solder seeds of some shape, which may be seeds are applied and then energy is added in a reflow process to melt the solder seeds and cause them to wet the contact pads (304, 309). After the reflow, energy is removed and the solder solidifies, wetting and metallurgically bonding to the pads. In a preferred embodiment of the present invention, while the solder is molten and the pads are wetted, the two devices are moved nominally further apart, creating the column effect seen in FIG. 3. The wetted area remains essentially the same diameter as before the movement, and the surface tension effects cause a narrowing at the waist, providing a considerably narrowed diameter substantially halfway between the pads, as shown. The solder columns are than allowed to solidify at the greater separation distance between the two devices.

In an alternative embodiment, to provide extended solder columns on a single device (303 of FIG. 3), which may then be shipped to another place for ultimate connection to another device or board, a special tool is used to temporarily wet to molten solder balls on 303, and then to draw those balls into extended columns 305, after which the connection to the tool (represented in this description also by element 304), is discontinued. The tool simulates a number of contact pads (one is shown as 304 in FIG. 3), and the pads are made of a material, or treated such, that the wetted surface is much less adherent to the solder when the solder solidifies, than is the case for a contact pad that is meant for a permanent connection. The tool may then be withdrawn after the extended columns solidify, separating at the surface of 304. Alternatively, the tool is made with a flash-heating facility which allows the connection to be quickly broken at the tool-pad surfaces without melting or otherwise deforming the newly-extended solder column.

There are a variety of other ways that taller and thinner solder columns may be formed than those that result in the known art, using techniques such as masking, metal deposition through a mask, and the like, and many such techniques will occur to the skilled artisan, after the teaching herein that the narrowed, extended column is preferable.

By utilizing extended solder columns such as column 305 as described in this example, the combination of very fine pitch and large number of I/O connections, typical of current high density flip-chip applications, is achievable while eliminating the need for expensive and time-consuming underfill processes such as are typically required in conventional applications. Such an enhanced connection technique and apparatus enables the manufacturer or assembler to use a generic die in the production of a high-density CSP flip-chip device having solder interconnections between the die and substrate or PCB that are significantly more reliable and less prone to damage from the various factors such as have been described.

Similar advantages pertaining to solder joint flexibility and reliability may also be realized by forming extended solder columns, such as described for die 301 of FIG. 3, directly on the connection points, or pads, of the substrate or intermediate PCB to which a generic flip-chip device is to be mounted. In such a way, a manufacturer or assembler may utilize generic chips consigned by a customer, for example, in the production of a highly reliable flip-chip package that is produced efficiently and economically

FIG. 4 is an enlarged broken view of a portion of a fine-pitch chip scale package (CSP) substrate with extended solder columns according to an embodiment of present invention. Substrate 409 in this example is a conventional intermediate PCB for mounting a silicon die for production of a flip-chip BGA device of very fine pitch and high-density such as is described for FIG. 3. In this example substrate 409 may be manufactured of organic or ceramic material, or some other material such as is commonly used in current art, and may be of single-layer or multi-layer design, depending on the complexity and number of I/Os required in the application. Substrate 409 has a plurality of contact pads 410 for interconnecting circuits within substrate 409 to those of a flip-chip device that is mounted thereupon, and ultimately to circuits outside of the package in which substrate 409 is used.

Extended solder columns 405, similar to solder columns 305 of FIG. 3, are provided in this example for enabling a flexible and reliable solder joint for interconnecting substrate 409 to a generic BGA silicon die, or to an enhanced, solder-bumped silicon die such as die 301 of FIG. 3. Enhanced solder columns 405 are formed upon, and metallurgically attached to pads 410 of substrate 409 utilizing methods similar to those used for solder columns 305 of FIG. 3. The same methods described above are used.

The enhanced processes described herein for using extended solder columns on flip-chip substrates or silicon dies in the assembly of a flip-chip package provides a solder joint that enables greater reliability and longevity of the solder connection between the die and substrate without the use of expensive and time-consuming underfill processes. The problem of solder joint reliability in high-density applications such as has been described is thereby addressed by the invention.

As described earlier, relentless miniaturization trends in portable electronic products that utilize integrated circuit devices has driven much work in the field that is focused on reducing the package size of an integrated device while increasing performance and functionality of the device, in addition to work focused on solder joint performance and reliability. The practical limits of solder joint miniaturization in high-density CSP applications is quickly being reached in current technology, and the use of multi-level electronics assembly utilizing chip-stacking is widely perceived in the industry as a viable solution to increasing I/O capacity in a chip package without unduly increasing the footprint of the device. However, its use in mainstream electronics manufacturing has been limited due to complexity of stacking chips, packages or modules, particularly for low-volume specialized applications.

Currently, the biggest trend in chip-stacking technology is a simple approach with a small number of chips in one package. An enhanced chip-stacking method and apparatus known to the inventor utilizing interposer technology with BGA flip-chip processes, as taught in the co-pending patent application bearing Ser. No. 09/915,708, referenced as a priority document above, provides a chip-stacking methodology that greatly increases the memory capacity of a memory module, for example, while maintaining the small footprint of a single integrated device. In the present invention it is an object of the inventor to utilize an alternative embodiment of such enhanced interposer interconnection technology to further increase the I/O capacity and functional performance of a stacked chip assembly without unduly increasing the footprint of the device.

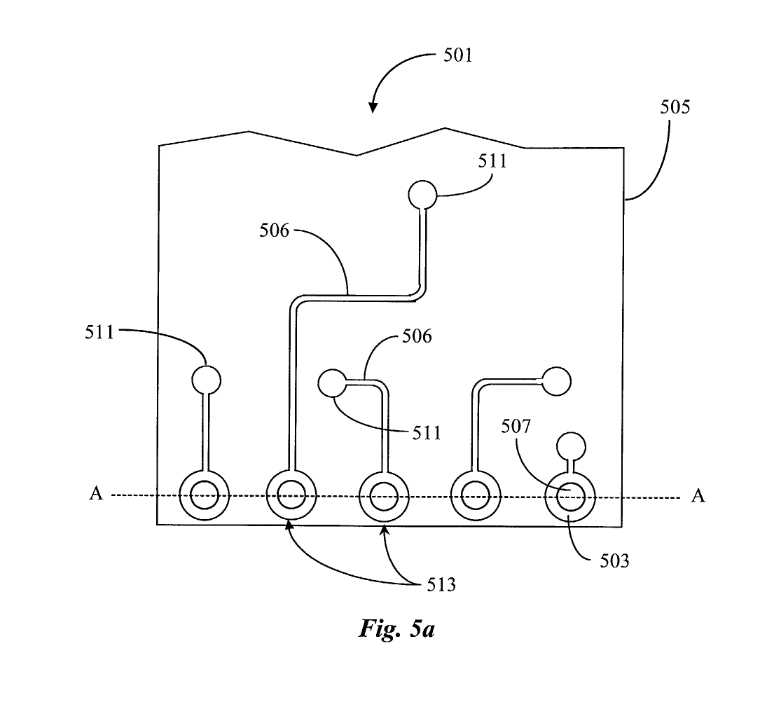

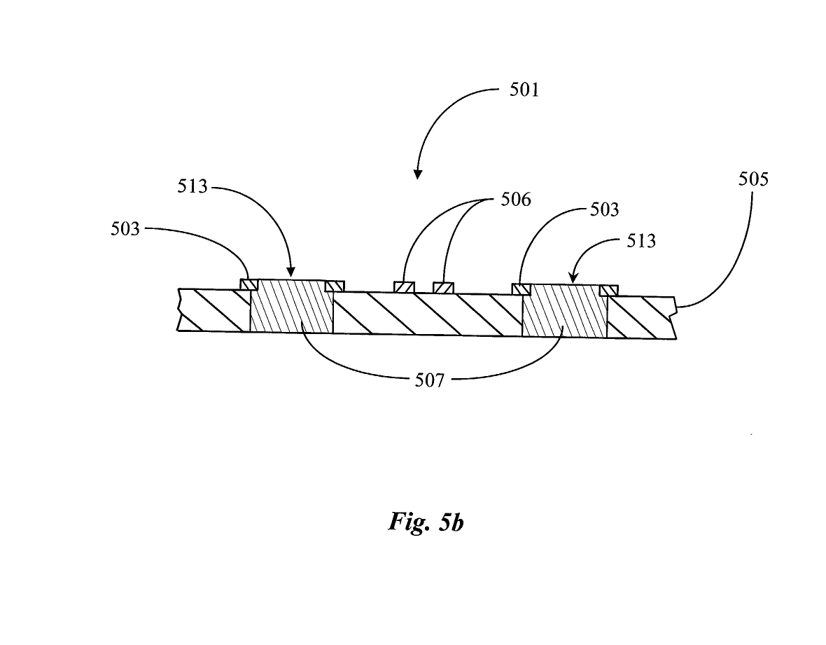

FIG. 5a is a broken plan view of an interconnection interposer similar to that used as described in co-pending priority patent application Ser. No. 09/915,708, but with key differences enabling a new and novel chip-stacking technique as described below according to an embodiment of the present invention. Interposer 501 is shown in this view greatly simplified to better illustrate the key elements of the new and novel interconnect system provided by the invention. Interposer 501 is, in a preferred embodiment, of the form of a thin non-conductive BT resin (insulator) having a conductive metal on one side, etched and patterned to provide conductive paths (traces), much like a miniature print circuit board. Interposer 501 is preferably prefabricated for each application after the conductive metal is applied to provide for the circuitry paths required for specific device designs which will be clearer following descriptions below. An important function of interposer 501 is to electrically connect individual ones of the solder balls of an attached flip-chip die to electrical contact pads along the outer periphery of the interposer, where connection may then be made to circuitry outside of a chip-stack package utilizing interposer 501.

In the example provided in FIG. 5, interposer 501 has connection pads 511 implemented at strategic positions on base material 505. The purpose of pads 511 is for providing contact for the solder balls of a flip-chip BGA device such as that of die 203 of FIG. 2, or for a similar BGA flip-chip device, which may be a DRAM memory chip or some other type of integrated BGA device. Traces 506 from pads 511 are implemented to provide single communication to another plurality of pads 513, which may be compound pads, which are implemented along the edge of interposer 501 in this example. For reasons of simplicity pads 513 are shown in this example implemented along only one edge of interposer 501. It can be assumed in this embodiment that pads 513 may be located along any or all edge of interposer 501, not necessarily along only the one edge as shown. It can also be assumed that pads 513 may be linearly arranged around the periphery of interposer 501, along any edge of the periphery of interposer 501, similarly to the configuration shown in this view for pads 513, and connected to an additional plurality of pads 511 (not shown) by additional traces 506 (also not shown).

Pads 513 each comprise a metal ring 503 (such as copper in the case of the conductive traces 506 being made of copper), and through holes extending completely through base material 505 of interposer 501. The through holes of pads 513, in a preferred embodiment, are filled with a conductive material such as solder or some other type of highly conductive filler, allowing conductivity through base material 505. Pads 513 in this embodiment, with traces 506 and pads 511, allow multiple I/O points of a flip-chip device such as die 203 of FIG. 2 to simultaneously connect to circuitry outside of the stacked BGA package, facilitating communication between a flipped BGA device and connection points to circuitry of an intermediate substrate or PCB, for example, to which the chip stack may be mounted according to an embodiment of the present invention.

In this example, to enable interposer 501 to achieve significant electrical conductivity between pads 511 and traces 506, to circuitry outside of interposer 501, when used in a new and novel chip stacking technique described below, the edge or edges of interposer 501 on which pads 513 are located, are physically cut off through about the center of pads 513, in this example the cut being indicated as section line A-A. The edge or edges that are cut off of interposer 501 along the center of pads 513 leaves copper rings 503 and conductive filler material 507 in the shape of a half-circle which forms a substantial conductive surface facing outward from interposer 501. The remaining conductive areas of pads 513 formed by the cut are better understood following description of FIG. 5b below.

FIG. 5b is an enlarged, broken edge-on view (inn a direction parallel to the primary surfaces of the interposer) of a portion of interconnection interposer 501 of FIG. 5a. In this exemplary view a pair of edge pads 513 of interposer 501 are shown, the cross-section view taken through edge pads 513 along section line A-A of FIG. 5a. Pads 513 in this view are shown having metal rings 503 and conductive filler material 507 extending completely through a hole in base material 505, the conductive filler material 507 also extending up through the hole formed by ring 503, such that conductivity is possible along any vertical portion of pad 513. As described above, pads and traces are made possible on base material 505 by first forming a conductive layer on base material, and then selectively removing portions of the conductive layer, the conductive layer, in a preferred embodiment being copper.

It can be assumed in this example that pads 513, having metal rings 503 metallurgically attached to conductive filler material 507, are connected to pads 511 and traces 506, which are not seen in this view. Metal ring 503 provides additional structural support for the connections formed by cutting through edge pads 513.

As mentioned earlier, the relentless miniaturization trends in portable electronic products that utilize integrated circuit devices has driven much work in the field that is focused on reducing the package size of an integrated device while increasing performance and functionality of the device, in addition to work focused on solder joint performance and reliability. The practical limits of solder joint miniaturization in high-density CSP applications is quickly being reached in current technology, and the use of multi-level electronics assembly utilizing chip-stacking is widely perceived in the industry as a viable solution to increasing I/O capacity in a chip package without unduly increasing the footprint of the device. However, its use in mainstream electronics manufacturing has been limited due to the complexity of stacking chips, packages or modules, particularly for low-volume specialized applications.

Currently, the largest trend in chip-stacking technology is a simple approach with a small number of chips in one package. An enhanced chip-stacking method and apparatus known to the inventor utilizing interposer technology with BGA flip-chip processes, as taught in the co-pending patent application bearing Ser. No. 09/915,708, referenced as a priority document, provides a chip-stacking methodology that greatly increases the memory capacity of a memory module, for example, while maintaining the small footprint of a single integrated device. In the present patent application it is an object of the invention to extend enhanced interposer interconnection technology to further increase the I/O capacity and function performance of a stacked chip assembly without unduly increasing the footprint of the device.

In the present patent application it is an object to utilize the enhanced interconnection interposer 501 of FIG. 5a, as described in the embodiment presented, to enable a further increase the I/O capacity and function performance by enabling a new and novel approach to vertically stacking flip-chip BGA devices, as is described below, without increasing the footprint surface area of the device. As mentioned earlier, the practical limits of solder joint miniaturization in high-density CSP applications is quickly reaching the limits in current technology, and vertical chip stacking is seen as a viable and preferred solution for immediate, low-cost increases in I/O capacity of a flip-chip package.

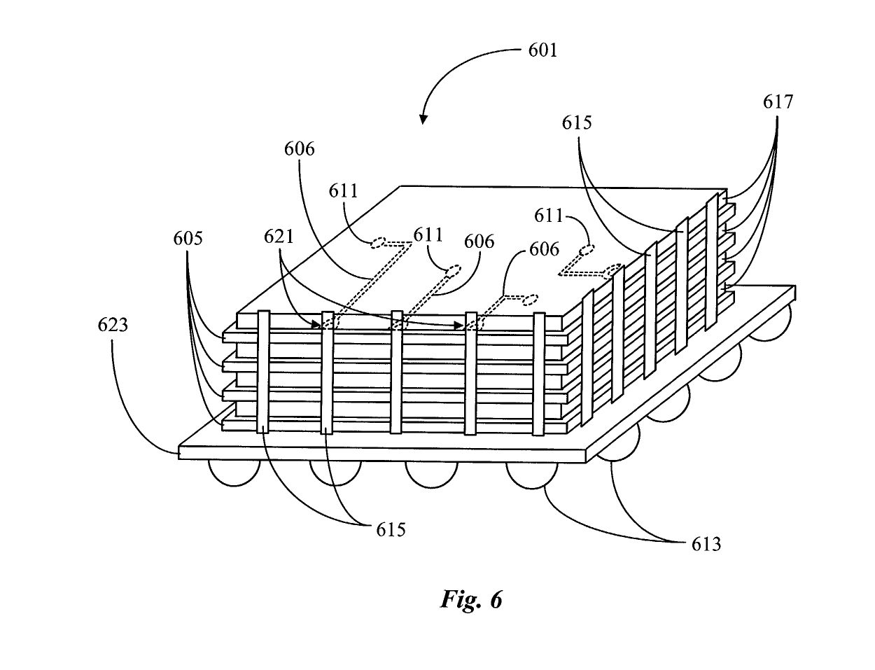

FIG. 6 is a representative perspective view of a vertically-stacked flip-chip package assembled and interconnected according to an embodiment of the present invention. In this exemplary view a plurality of flip-chip BGA devices are vertically stacked and interconnected utilizing an embodiment of interposer 501 of FIG. 5a, in conjunction with a new and novel method and apparatus for interconnecting such stacked chips to each other, and ultimately to an intermediate flip-chip substrate. Chip package 601 comprises a plurality of stacked BGA flip-chip devices, in this example a total of 4 such devices, represented as chips 617. Each chip 617 in this example represents a typical BGA flip-chip DRAM device such as die 203 of FIG. 2, or in other embodiments may be one of a variety of devices such as SRAMs, DSPs or some other type of flip-chip BGA integrated device. Each chip 617 is mounted to an enhanced interposer 605 that is similar in form and function to that described for interposer 501 of FIG. 5a. Although, for reasons of simplicity, many details are not shown in this view, it may be assumed that each chip 617 has solder bumps on the connection side of the chip, which are connected to strategically-located connection pads on the upper surface of the interior region of each interposer 605, and also that the connection pads of interposers 605 are connected to traces also formed on the upper surface of each interposer 605. The forming of pads 611 and traces 606 of interposer 605 is accomplished using similar methods as described for interposer 501 of FIG. 5a. Simple representations are given in this view of such connection pads and traces, and are indicated in the hidden view by pads 611 and traces 606, which are in this example located below the uppermost chip 617 and on the upper surface of the uppermost interposer 605.

Traces 606 on interposer 605 lead from pads 611 outward to the periphery of the interposer interconnected to connection pads 621 formed by manually cutting the edge or edges of interposer 605, similarly to the process used for interposer 501 of FIG. 5a, where a physical cut is formed along section line A-A through the center of edge pads 513. It may also be assumed that each interposer 605 has a plurality of pads 611, traces 606 and edge-connection pads 621. It may also be assumed that, although it is not shown in this view, connection pads 621 located along the edges of interposers 605 may be located on any edge of interposer 605, not necessarily only those shown in this view.

The stacked chips 617 and interposers 605 are supported by, and mounted to, an intermediate BGA substrate 623 in this example, substrate 623 being similar in form and function to a typical BGA substrate such as that used for a conventional flip-chip BGA package, with the exception of new and novel circuitry and connection points whose purpose is electrically connecting the stacked chips 617 and interposers 605 to substrate 623 for redistribution of signals from the stacked assembly to the final printed wire board (not shown) through large solder balls 613. Traces 606 of each interposer 605 provide the signal paths leading from pads 611 to connection pads 621, and connection pads 621 of each interposer 605 are interconnected by a plurality of vertically oriented bus bars 615. Since there is only one connection side to each chip 617, chip-to-chip communication and chip-to-board communication are both enabled by bus bars 615 which interconnect each interposer 605, each interposer 605 connected to the connection side of each chip 617.

In alternative embodiments bus bars 615 may take one of several different forms, such as a highly conductive wire or some other conductive medium. Although detail is not given here as it is not particularly pertinent to the invention, bus bars 615 are connected to the circuitry of substrate 623 for the purpose of redistribution by use of conductive pads on substrate 623 or by some other known method. As is true for connection pads 621, bus bars 615 may be located on either edge of the stacked chip assembly of chip package 601, although they are shown in this view only located on one front and side edge.

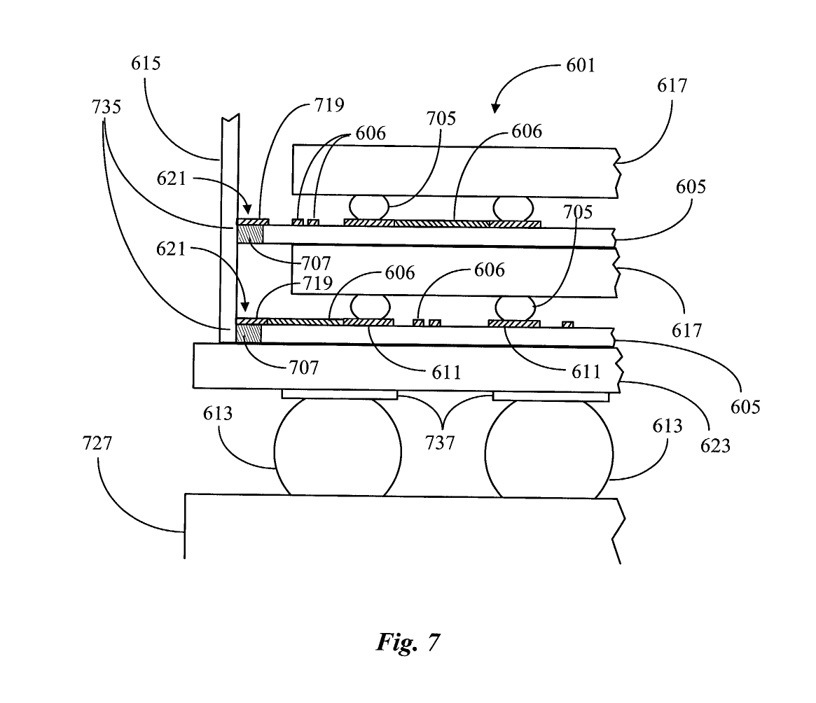

FIG. 7 is a broken cross-section view of a portion of stacked flip-chip package 601 of FIG. 6, enlarged to show greater detail. FIG. 7 is also an exemplary view showing and describing only those details that are pertinent to the present invention. A pair of chips 617 is clearly shown in this view, each attached individually to a dedicated interposer 605. Chips 617 and interposer is 605 are vertically stacked as a shown in the simplified view of FIG. 6. Solder balls 705, not seen in FIG. 6, are clearly seen in this view metallurgically attached to chips 617, providing the solder joint connections between the connection points (not shown) of chips 617 and metal pads 611 of interposer 605. Traces 606, which are connected to, and provide the outward signal paths for pads 611, are also clearly seen in this view traveling in both lateral and perpendicular direction, leading to edge pads 621 which were formed, as previously described, by cutting the edge or edges off of interposers 605 through center of edge pads 621, similarly to the method described for interposer 501 of FIG. 5. Metal rings 719, which are now in the shape of a half-circle, also similar to those produced, using the cutting method of edge pads 513 of FIG. 1, as well as the conductive filler material 707, are also clearly seen in this view. Edge pads 621 are metallurgically and soundly connected to the vertical bus bars 615 utilizing a common connection method known in the art, such as by solder joint accomplished by reflow. Vertical bus bar 615 is electronically connected to substrate 623 also utilizing a connection method known in the art, such as soldering or welding.

It may be more clearly understood by reference to this enlarged view of a portion of chip package 601 that the signal paths and redistribution method utilized in the preferred embodiment shown, allows efficient chip-to-chip and chip-to-board communication through interposers 605 and bus bars 615. Signals from chips 617 travel through solder balls 705 to interposer pads 611, along interposer traces 606 to edge pads 621, edge pads 621 comprising the reinforcing metal ring 719 and conductive filler material 707, and then through vertical bus bar 615 to the circuitry of intermediate substrate 623. Electronic connection of the components of chip stack package 601 to a final printed wiring board (PWB) 727 is achieved through substrate pads 737, located on the bottom surface of substrate 623 to which large solder balls 613 or metallurgically attached, solder balls 613 been metallurgically attached to connection pads (not shown) of PWB 727.

Utilizing the new and novel chip stacking and interconnection methods shown and described in this example, I/O capacity is quickly and economically increased by vertically stacking and interconnecting additional sets of chips 617 and interposers 605, each set connected to another and to intermediate substrate PCB 623 by a plurality of vertical bus bars 615 which are strategically located along the edges of the chip stack to best propagate the signals for the particular application or device. Redistribution to the final PWB is then achieved by connection of larger solder balls between substrate 623 and PWB 727. The described chip-stacking and interconnection method provides a theoretically unlimited vertical stacking capability providing a short signal path for each stacked chip, thereby enabling a greatly increased I/O capacity compared to conventional chip stacking methods, without affecting the footprint of the device.

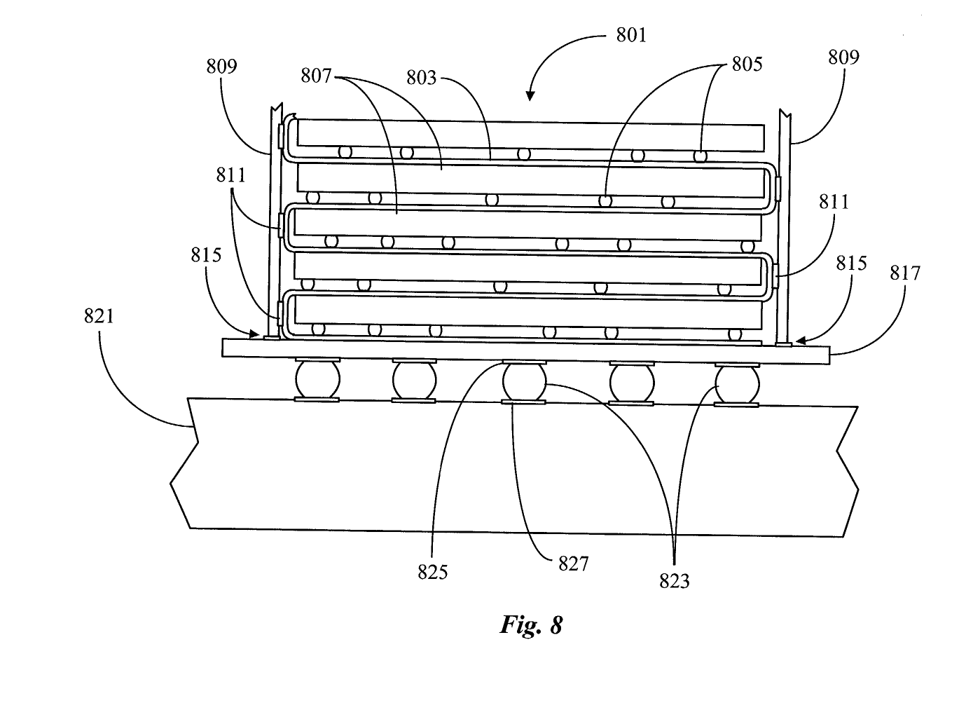

FIG. 8 is an enlarged broken cross-section view of a vertically stacked flip-chip package and interposer assembled and interconnected according to an alternative embodiment of the present invention. In this exemplary view many details not particularly pertinent to the present invention are omitted for reasons of simplicity.

Package 801 has a plurality of flip-chip BGA devices 807 similar to those used for chips 617 of FIG. 6 which are vertically stacked and, utilizing an enhanced interposer system, interconnected for communication to each other and to a BGA intermediate substrate circuit board for redistribution of signals to the final printed wiring board (PWB), utilizing many of the methods used for chip stack package 601 of FIG. 6. It is an object of the invention to utilize the many advantages of vertical chip stacking, as have been previously described, in conjunction with several aspects of the interposer interconnection method utilized as described for package 601 of FIG. 6, but having key differences in its form and use, as is described below.

Package 801 comprises a plurality of chips 807, which, in this example, represent DRAM memory chips manufactured using current BGA solder ball technology. In other alternative embodiments however, as is true for other chip packages described above, chips 807 may represent chips of another type, such as SRAMs, DSPs or some other type of chip. Chips 807 have solder balls 805 metallurgically attached to connection pads (not shown) on the connection side of the chip, connecting to circuitry within chips 807. In this view only a small number of solder balls 805 are shown for reasons of simplicity, as it should be apparent that in a typical application a much greater number of solder balls exist for chips 807.

An enhanced interposer interconnection approach is used for package 801 for providing signal paths from the solder connections of solder balls 805 of chips 807 to circuits outside of the chip package. Interposer 803 is provided in this example as an alternative embodiment of the present invention for vertically stacking and interconnecting generic BGA chips utilizing interposer technology. Interposer 803 utilizes conductive metal on a non-conductive film, the metal etched to provide necessary conductive paths through connection pads and traces similarly to interposers 605 of the detail drawing of FIG. 7. However, unlike interposers 605 of FIG. 7, which are separate interposers, slightly larger in surface area then chips 617 and positioned between each chip in the chip stack, interposer 803 in this embodiment is of a continuous unbroken length, folded and routed above and below each chip so as to encompass the upper at lower surface of each chip 807 of chip stack package 801.

Interposer 803 is routed in such a way that all of solder balls 805 of chips 803 in the chip stack may make electrical contact to a metal connection surface on one or another side of interposer 803. A preferred embodiment of interposer 803 is designed for a specific application and silicon BGA device, having connection pads strategically placed for the grid array of each interconnected chip, and traces leading from the connection pads outward from the center neutral point of the chip and to connection interfaces 811 located on a peripheral edge of the stack package 801. The purpose of interfaces 811 are for providing a conductive interface between traces of interposer 803 and a connecting bus bar 809, similar to the redistribution method as described for package 601 of FIG. 7. For reasons of simplicity only two bus bars 809 are shown in this exemplary view, but in a typical application a much greater number of bus bars may be used, strategically positioned along any edge of the periphery of package 801. Bus bars 809 are metallurgically attached to a connection pad of substrate 817 through interfaces 815, providing the signal path to printed wiring board (PWB) 821 through large solder balls 823 and metallurgically attached connection pads 825 and 827.

It will be apparent to one with skill in the art that the present invention may be practiced in variations of the presented configurations without departing from the spirit and scope of the present invention. The inventor has provided exemplary views for describing at least one embodiment of the present invention, therefore, the inclusion of illustrated devices, described processes, and materials in the examples presented should not be construed as a limitation in any way to the practice of the invention. Furthermore, the functionality described herein, although illustrated primarily with reference to BGA memory chips should be recognized as applicable also to various types to BGA chips and circuitry beyond that of those described in examples. Therefore, the method and apparatus of the present invention should be afforded the broadest possible scope under examination. The spirit and scope of the present invention is limited only by the claims that follow.

What is claimed is:

1. A method for forming an extended solder column on a contact pad of an electronic device, comprising steps of:
(a) applying a solder seed to the contact pad;
(b) contacting the seed with a surface substantially parallel to and opposite the contact pad, with the seed between the surface and the pad;
(c) melting the seed to wet the contact pad and the surface;
(d) extending the relative separation of the surface and the contact pad, drawing the molten seed into a column; and
(e) solidifying the resultant column.

2. The method of claim 1 comprising multiple contact pads on the electronic device and multiple surfaces, one for each contact pad.

3. The method of claim 1 wherein the surface is a second contact pad of a second electronic device, such that, after step (e) the column forms an electrical contact path between the two contact pads.

4. The method of claim 2 wherein the surfaces are second contact pads of a second electronic device, such that, after step (e), the columns form electronic contact paths between the associated contact pads.

5. The method of claim 2 comprising a further step (f) for breaking the bond at the surface to leave extended solder columns metallurgically bonded to the contact pads.

6. The method of claim 5 wherein the bonds to the surfaces are broken by heating the surface.

7. An integrated circuit (IC) assembly for mounting to a surface of a device board comprising:
a plurality of planar ICs each having first contact pads on one surface, which connect to electronic devices in the IC, and conductive columns metallurgically bonded to and extending from individual ones of the contact pads;
a plurality of planar interposers parallel to and interspersed with the plurality of planar ICs, each interposer having second contact pads on at least one surface connected to the conductive columns, and traces on at least one surface connected to the second contact pads, individual ones of the traces leading to electrical contact regions on an edge at a periphery of the individual interposer, the contact regions facing away from the interposer in a direction parallel with the one surface; and
a plurality of conductive bars extending in a direction orthogonal to the planar ICs and interposers, the conductive bars metallurgically bonded to individual ones of the outward-facing peripheral contact regions, the bars constraining the interspersed interposers and ICs into a closely-spaced stack and providing common signal paths from the stacked ICs.

8. The assembly of claim 7 wherein the conductive bars end on one side at a plane away from one end of the stacked ICs, and are connected to an intermediary board having traces and third contact pads for connecting the IC stack to a printed circuit board (PCB).

9. The assembly of claim 7, wherein the ICs are memory chips and the PCB is a memory board.

10. The assembly of claim 7, further comprising a polymer material imposed between interspersed interposers and planar ICs, the polymer layer providing additional support for the stack and the conductive columns.

11. A memory module for providing memory resources to a computerized appliance comprising:
a printed circuit board (PCB) having at least one location for mounting an IC assembly; and
an integrated circuit (IC) assembly mounted to the PCB, the assembly comprising a plurality of planar ICs each having first contact pads on one surface, which connect to electronic devices in the IC, and conductive columns metallurgically bonded to and extending from individual ones of the contact pads, a plurality of planar interposers parallel to and interspersed with the plurality of planar ICs, each interposer having second contact pads on at least one surface connected to the conductive columns, and traces on at least one surface connected to the second contact pads, individual ones of the traces leading to electrical contact regions on an edge at a periphery of the individual interposer, the contact regions facing away from the interposer in a direction parallel with the one surface, and a plurality of conductive bars extending in a direction orthogonal to the planar ICs and interposers, the conductive bars metallurgically bonded to individual ones of the outward-facing peripheral contact regions, the bars constraining the interspersed interposers and ICs into a closely-spaced stack and providing common signal paths from the stacked ICs.

12. The memory module of claim 11, comprising a plurality of IC packages mounted to both sides of the circuit board of the module.

13. An interposer for providing conductive and nonconductive interface between opposing leads of ICs stacked in a packaged IC assembly comprising:
a non-conductive sheet;
metal contact pads and traces formed on the non-conductive sheet, including openings through the non-conductive sheet to expose regions of conductive contact pads or traces; and
contact regions implemented at a periphery of the non-conductive sheet, connected to traces on the sheet, and facing outward in a direction parallel with the sheet.

14. The interposer of claim 13, wherein the conductive traces and contact pads are formed from a copper foil applied to the non-conductive sheet by an adhesive.

15. The interposing contact element of claim 14, wherein the metal contact pads and traces are formed in a metallic film layer deposited on the interfacing material using one of a deposition, spin-on, or sputtering technology.

16. The interposer of claim 13, wherein the non-conductive sheet is formed from a BT resin.

17. The interposer of claim 13 wherein the contact regions are formed by filling holes along a periphery of the non-conductive sheet with solder, then trimming the sheet through the solder-filled holes.

18. An integrated circuit (IC) assembly for mounting to a surface of a device board comprising:
a plurality of planar ICs each having first contact pads on one surface, which connect to electronic devices in the IC, and conductive columns metallurgically bonded to and extending from individual ones of the contact pads;
an interposer formed of a length of foldable non-conductive material, folded to progressively space apart adjacent ones of the planar ICs in order, the folded interposer having second contact pads on at least one surface connected to the conductive columns of the plurality of ICs, and traces on at least one surface connected to the second contact pads, individual ones of the traces leading to electrical contact regions on the foldable interposer such that the contact regions face away from the assembly in a direction parallel with the plane of the ICs; and
a plurality of conductive bars extending in a direction orthogonal to the planar ICs, the conductive bars metallurgically bonded to individual ones of the outward-facing peripheral contact regions, the bars constraining the interposer and adjacent ICs into a closely-spaced stack and providing common signal paths from the stacked ICs.

19. The assembly of claim 18 wherein the conductive bars end on one side at a plane away from one end of the stacked ICs, and are connected to an 12 intermediary board having traces and third contact pads for connecting the IC stack to a printed circuit board (PCB).

20. The assembly of claim 18, wherein the ICs are memory chips and the PCB is a memory board.

21. The IC package of claim 7, further comprising a polymer material imposed between consecutive ICs and the interposer, the polymer material providing additional support for the stack and the conductive columns.
